(19) United States
(12) Patent Application Publication
(10) Pub. No.: US 2025/0323152 A1
(43) Pub. Date: Oct. 16, 2025

(54) INTEGRATED ANTENNA IC PACKAGE AND MANUFACTURING METHOD

(71) Applicant: TAIWAN SEMICONDUCTOR MANUFACTURING COMPANY, LTD., Hsinchu (TW)

(72) Inventors: Hsieh-Hung HSIEH, Hsinchu (TW); Tzu-Jin YEH, Hsinchu (TW); You Ru LEE, Hsinchu (TW); Yi Ping CHIANG, Hsinchu (TW)

(21) Appl. No.: 18/788,582

(22) Filed: Jul. 30, 2024

Related U.S. Application Data
(60) Provisional application No. 63/633,222, filed on Apr. 12, 2024.

(51) Int. Cl. H01L 23/528; H01L 21/8238; H01L 23/00; H01L 23/498; H01L 27/092; H01Q 1/22

(52) U.S. Cl. CPC H01L 23/528; H01L 24/08; H01Q 1/2283; H01L 23/49827; H01L 2224/08245; H10D 84/0165; H10D 84/038; H10D 84/85

(57) ABSTRACT

An IC package includes a transmitter and/or receiver positioned in a semiconductor die and including a signal terminal, a pad positioned on a first surface of the semiconductor die, the pad being electrically connected to the signal terminal, a passivation layer positioned on the first surface and including a first opening aligned with the pad, a first post-passivation interconnect (PPI) layer including a conductive path electrically connected to the pad, a second PPI layer including an antenna structure electrically connected to the conductive path, and a substrate positioned on a second surface of the semiconductor die opposite the passivation layer, the substrate including a plurality of through-substrate vias (TSVs) electrically coupled to the transmitter and/or receiver.

### PRIORITY CLAIM

The present application claims the priority of U.S. Provisional Application No. 63/633,222, filed Apr. 12, 2024, which is incorporated herein by reference in its entirety.

### BACKGROUND

In some applications, integrated circuits (ICs) include transmitters and/or receivers configured to perform telecommunication operations, e.g., as part of cellular or other radio networks or in radar applications. Advances in telecommunication technology often target enabling such operations to be performed using high frequency signals that support bandwidths larger than those of lower frequencies. In some cases, signals correspond to radio frequency (RF) bands that can range from 30 kilohertz (kHz) to 300 gigahertz (GHz).

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a cross-sectional view of an IC package, in accordance with some embodiments.

FIGS. 2A-2C are plan views of antenna structures, in accordance with some embodiments.

FIG. 3 is a schematic diagram of a transceiver circuit, in accordance with some embodiments.

FIG. 4 is a flowchart of a method of manufacturing an IC package, in accordance with some embodiments.

FIGS. 5A-5P are cross-sectional views of an IC package at various manufacturing stages, in accordance with some embodiments.

FIG. 6 is a flowchart of a method of operating an IC package, in accordance with some embodiments.

FIG. 7 is a block diagram of an IC manufacturing system, and an IC manufacturing flow associated therewith, in accordance with some embodiments.

### DETAILED DESCRIPTION

The following disclosure provides many different embodiments, or examples, for implementing different features of the provided subject matter. Specific examples of components, values, operations, materials, arrangements, or the like, are described below to simplify the present disclosure. These are, of course, merely examples and are not intended to be limiting. Other components, values, operations, materials, arrangements, or the like, are contemplated. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

In various embodiments, an integrated circuit (IC) package, e.g., a wafer-level chip-scale package (WLCSP), includes a semiconductor die including a transmitter and/or receiver, e.g., a transceiver, a pad electrically connected to the transmitter/receiver, and a passivation layer, a first post-passivation interconnect (PPI) layer including a conduction path electrically connected to the pad, a second PPI layer including an antenna structure electrically connected to the conduction path, and a substrate opposite the passivation layer and including through-substrate vias (TSVs) electrically coupled to the transmitter/receiver. The IC package thereby includes the transmitter/receiver configured to transmit and/or receive signals through an antenna or antenna array on a front side of the die while being powered and controlled from a back side of the die through the TSVs.

Transmitter/receiver operations are thereby capable of being performed using an assembly having a lower cost and smaller form factor than in other approaches, e.g., those in which antenna, power, and control connections are on a same side of a die, those in which a transmitter/receiver and antenna are integrated in a single die, and/or those including a flip-chip or waveguide antenna.

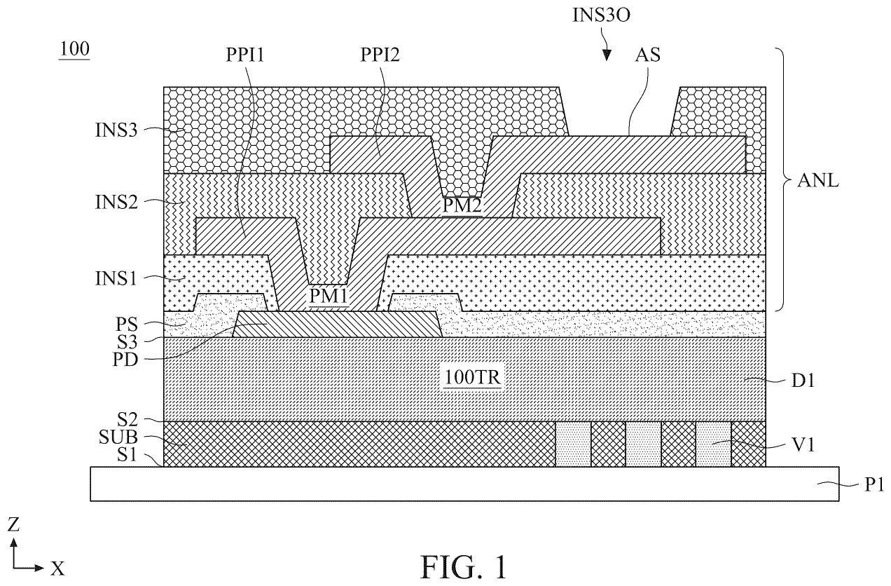

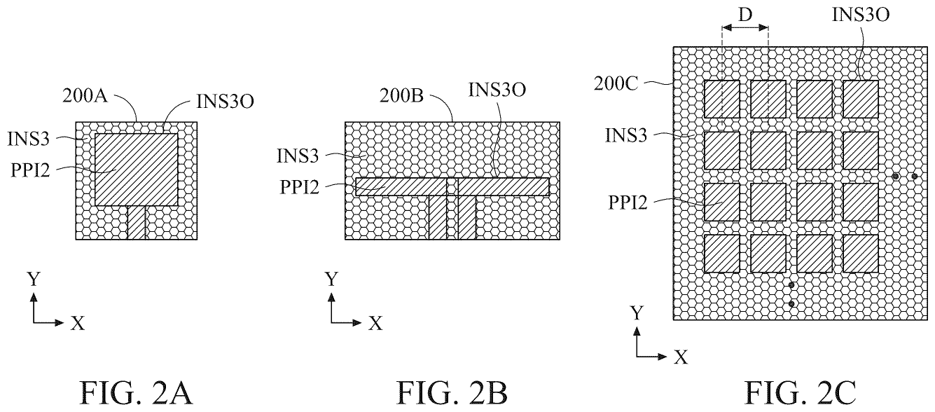

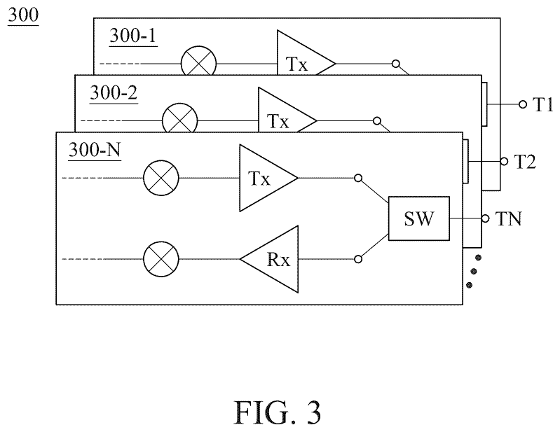

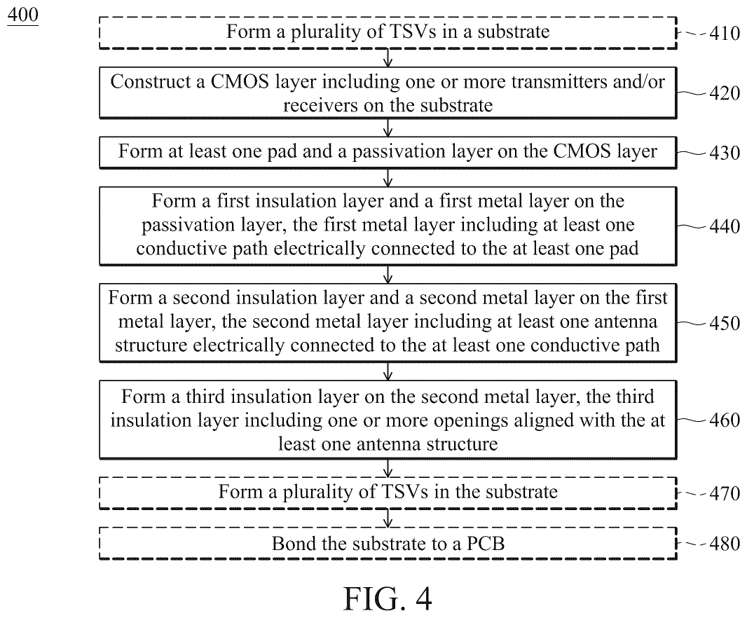

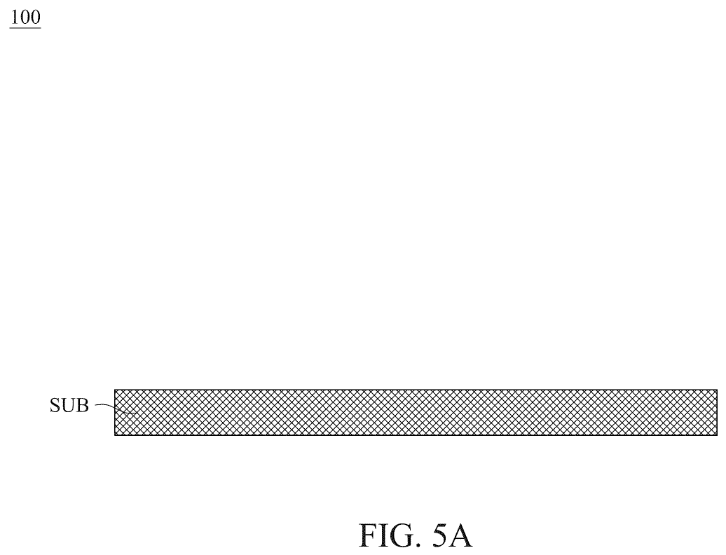

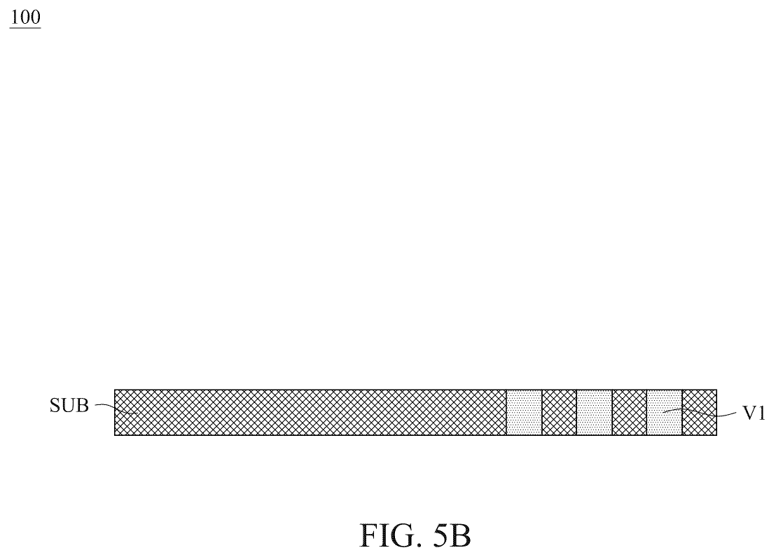

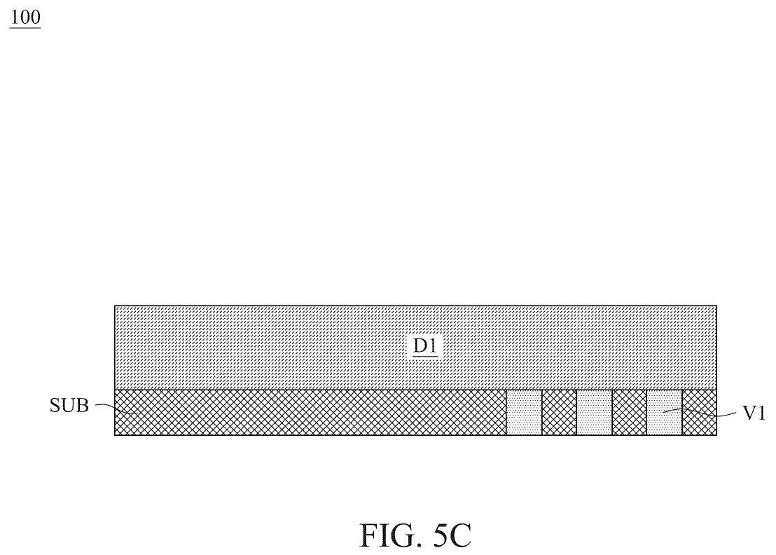

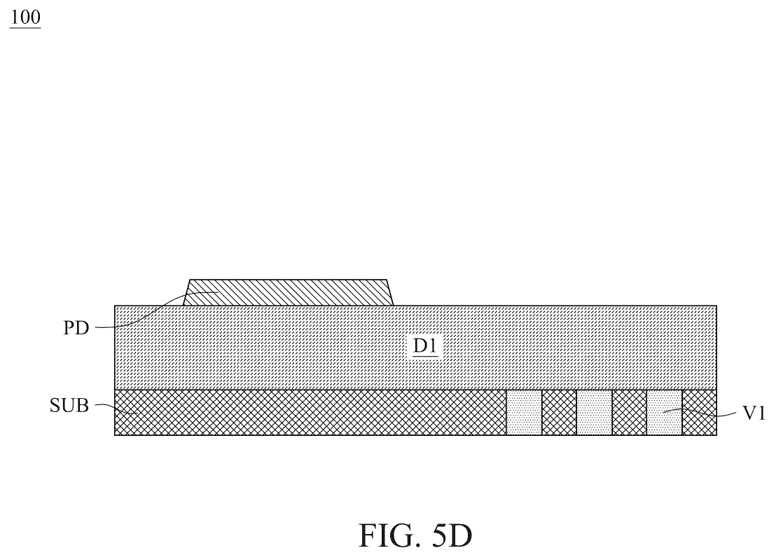

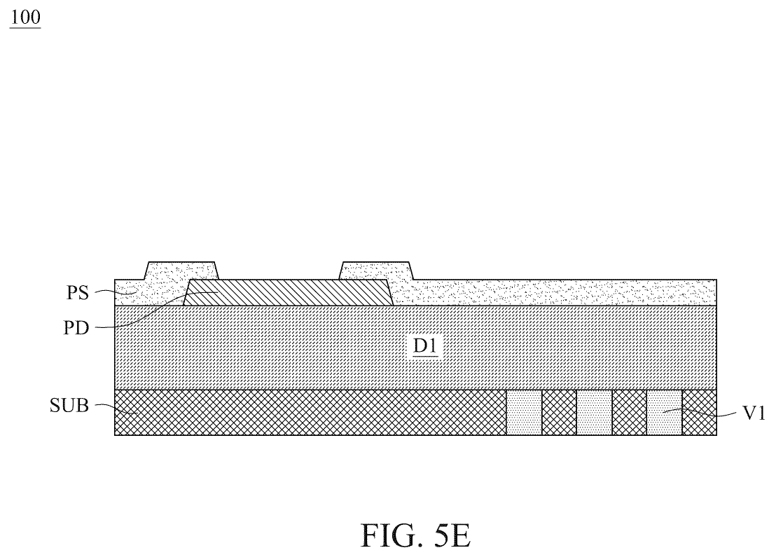

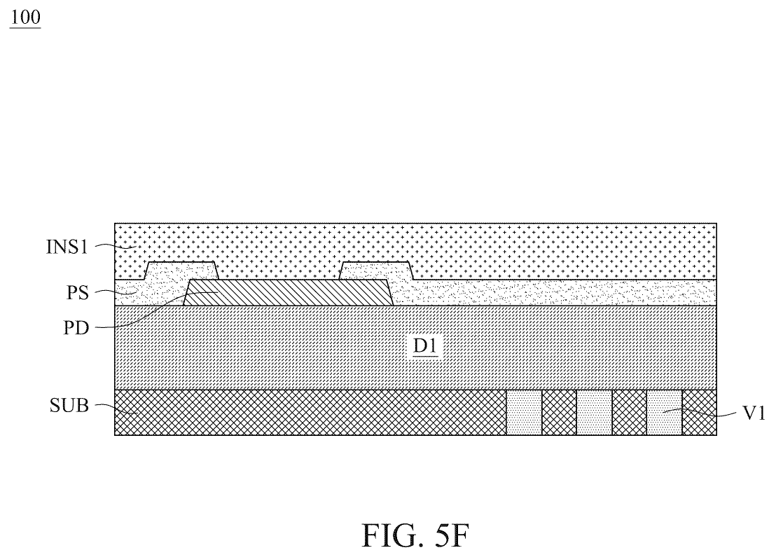

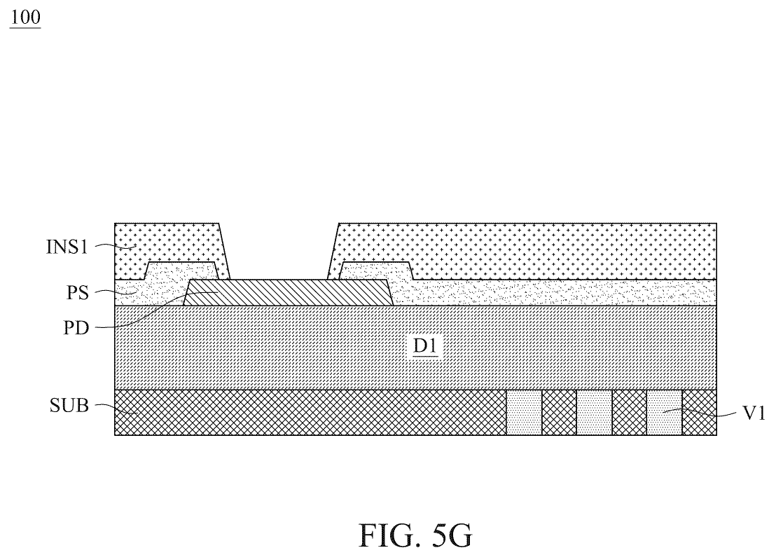

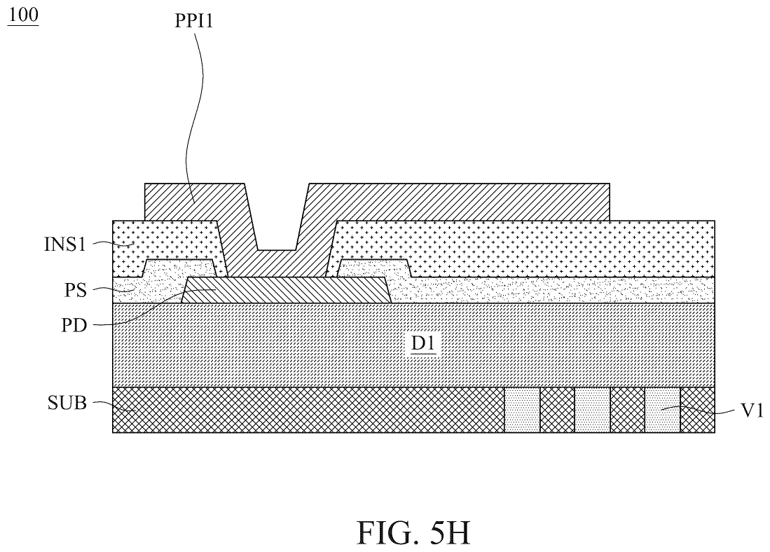

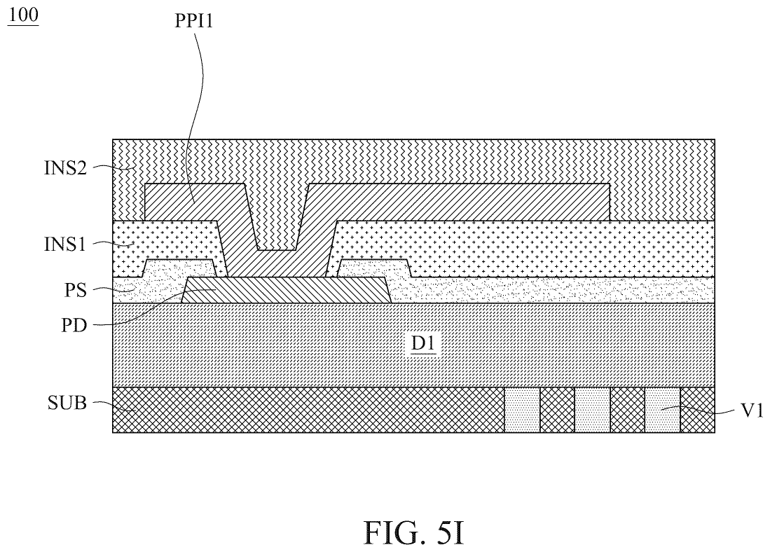

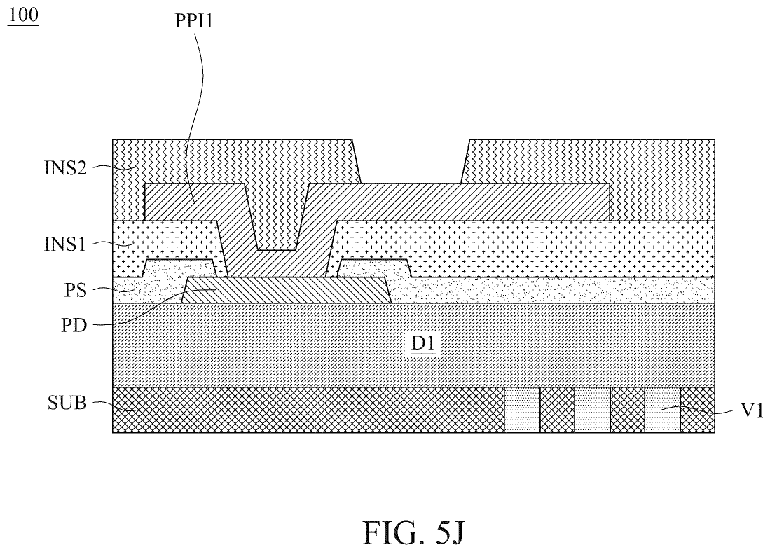

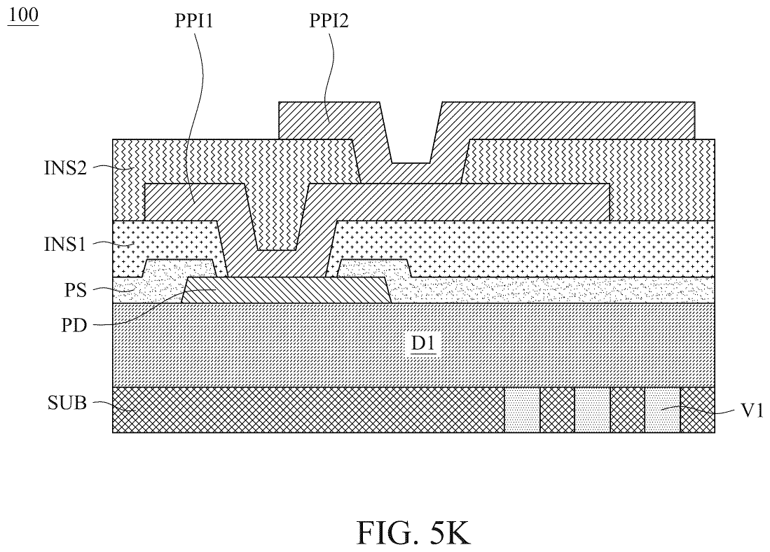

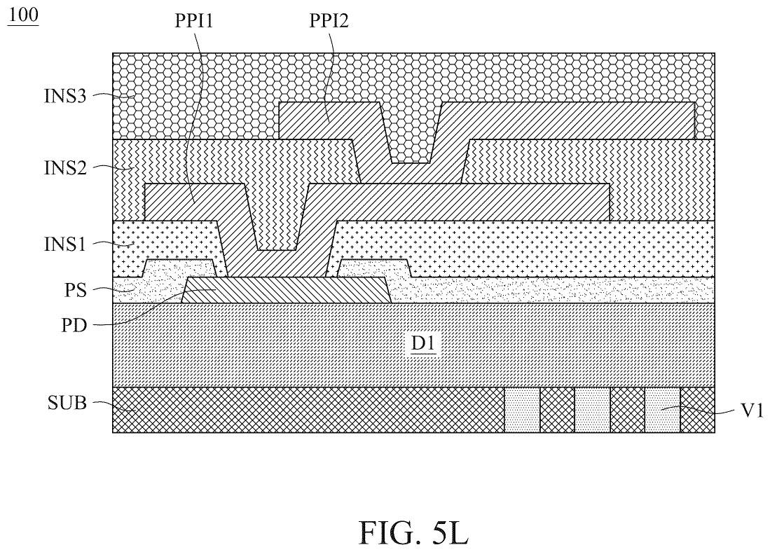

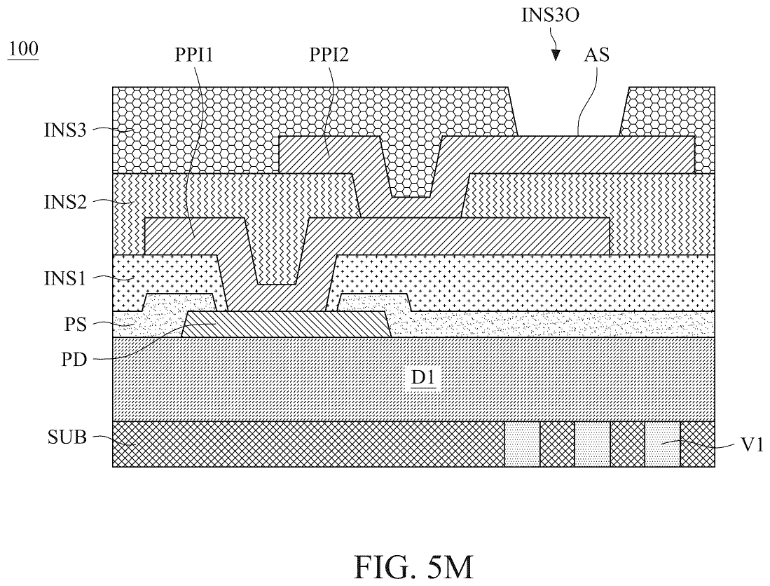

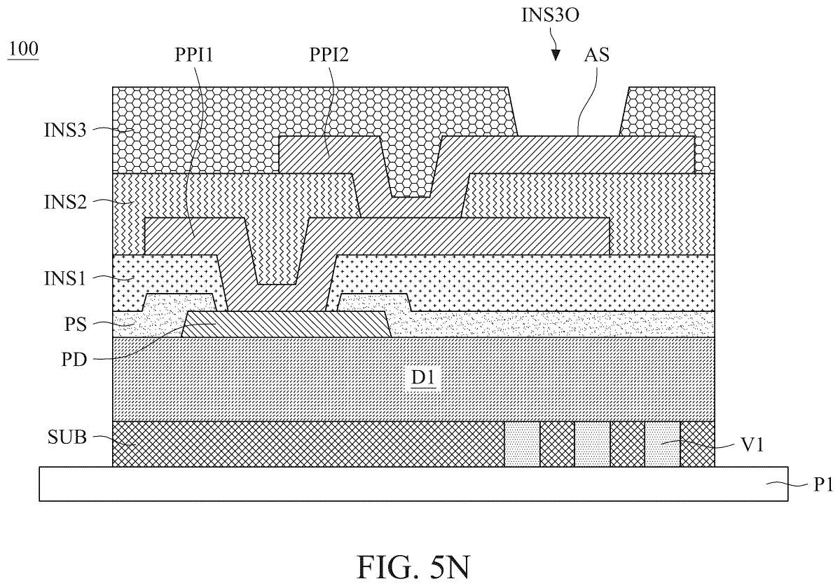

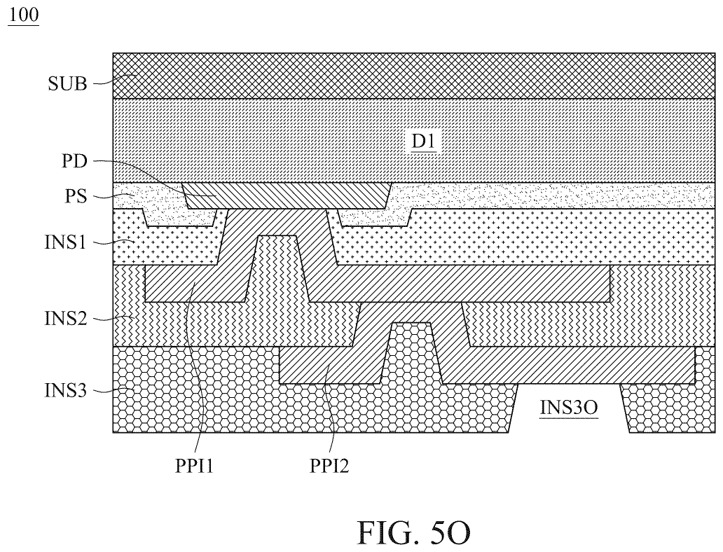

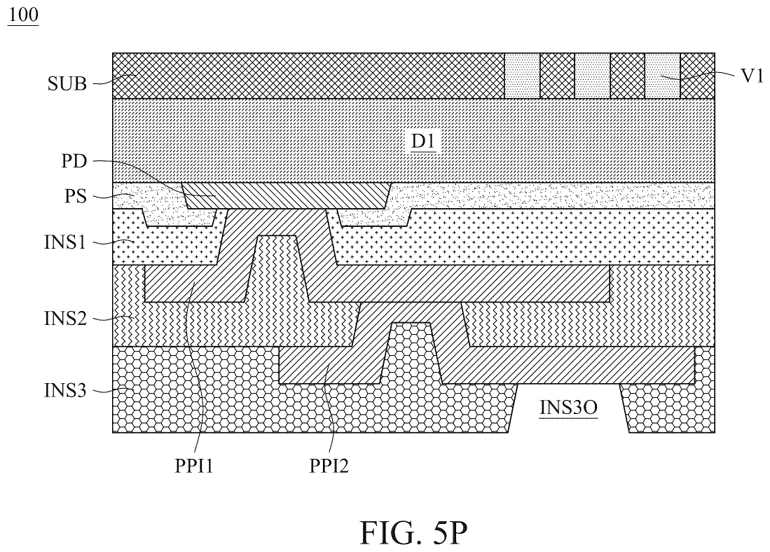

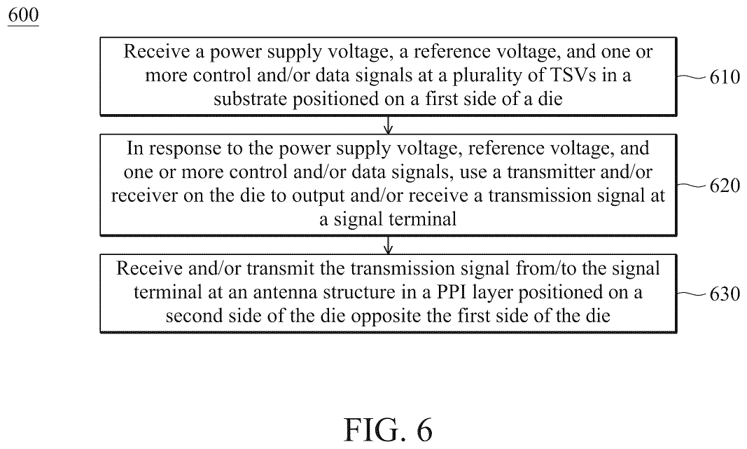

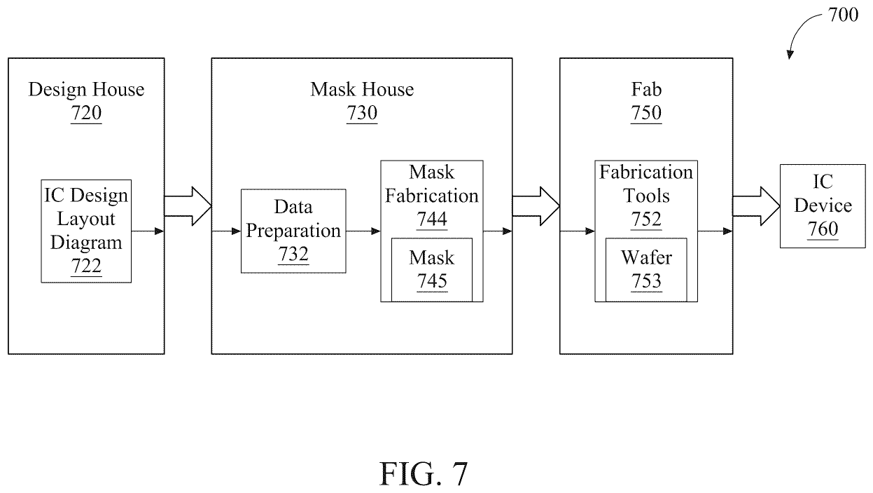

In accordance with various embodiments, FIG. 1 is a cross-sectional view of an IC package 100, FIGS. 2A-2C are plan views of antenna structures 200A-200C, FIG. 3 is a schematic diagram of a transceiver circuit 300, FIG. 4 is a flowchart of a method 400 of manufacturing an IC package, e.g., IC package 100, FIGS. 5A-5P are cross-sectional views of IC package 100 at various manufacturing stages, FIG. 6 is a flowchart of a method 600 of operating an IC package, and FIG. 7 is a block diagram of an IC manufacturing system 700 and an IC manufacturing flow associated therewith.

Each of the figures herein, e.g., FIGS. 1-2C and 5A-5P, is simplified for the purpose of illustration. The figures are views of IC structures, devices, and packages with various features included and excluded to facilitate the discussion below. In various embodiments, an IC structure, device and/or package includes one or more features corresponding to power distribution structures, metal interconnects, contacts, vias, gate structures, source/drain (S/D) structures, bulk connections, or other transistor elements, isolation structures, or the like, in addition to the features depicted in FIGS. 1-2C and 5A-5P.

The relative sizes, shapes, and dimensions of the various features depicted in FIGS. 1-2C and 5A-5P are non-limiting examples provided for the purpose of illustration. Features having relative sizes, shapes, and/or dimensions other than those depicted in FIGS. 1-2C and 5A-5P are within the scope of the present disclosure.

FIG. 1 depicts a cross-sectional view of IC package 100 and X and Z directions, in accordance with some embodiments. A Y direction (not shown) perpendicular to each of the X and Z directions extends into the depicted cross-section.

IC package 100 includes a printed circuit board (PCB) P1 bonded to a substrate SUB, a semiconductor die D1 including substrate SUB, one or more pads PD, and a passivation layer PS, and antenna layers ANL positioned on pad PD and passivation layer PS. In some embodiments, IC package 100 does not include PCB P1.

The cross-section depicted in FIG. 1 is simplified for the purpose of illustration such that limited instances of various features are depicted. In some embodiments, IC package 100 includes additional instances of some or all of the features depicted in FIG. 1, e.g., TSVs V1 and/or a pad PD.

In the embodiment depicted in FIG. 1, IC package 100 is configured as a WLCSP and is also referred to as WLCSP 100 in some embodiments. IC package 100 configured as another package type, e.g., a 3DIC package, is within the scope of the present disclosure.

PCB P1 is a rigid board including one or more insulating materials, e.g., a glass-reinforced epoxy material such as FR-4, and a plurality of metal, e.g., copper, traces (not shown) arranged on a surface S1 (also referred to as a surface S1 of substrate SUB and corresponding to an interface, e.g., a bond, between PCB P1 and substrate SUB). In some embodiments, PCB P1 includes a plurality of PCB pads (not shown) positioned at surface S1 and electrically connected to/included in the traces, and the interface is a solder joint including solder balls (not shown) attached to some or all of the PCB pads.

Substrate SUB is a structure including one or more semiconductor materials, e.g., silicon, and including a plurality of TSVs V1 including one or more conductive materials, e.g., a metal such as copper and/or aluminum, extending between surface S1 and a surface S2 (also referred to as a surface S2 of a complementary metal-oxide-semiconductor (CMOS) layer). In some embodiments, e.g., as depicted in FIG. 1, substrate SUB is also referred to as a CMOS substrate SUB.

Die D1 is a semiconductor die including one or more layers of combinations of semiconductor, conductor, and insulation materials configured as CMOS devices including one or more transmitters and/or receivers 100TR, e.g., one or more transceivers such as transceiver 300 discussed below with respect to FIG. 3, positioned on substrate SUB.

In some embodiments, die D1 and substrate SUB are a same bulk substrate and surface S2 corresponds to a location of active regions of CMOS transistors included in the one or more transmitters and/or receivers 100TR.

In some embodiments, e.g., as depicted in FIG. 1, substrate SUB is a semiconductor substrate, surface S2 includes one or more layers of insulating materials, e.g., silicon dioxide (SiO₂), die D1 includes an epitaxial layer of silicon, and die D1 including the epitaxial layer, substrate SUB, and surface S2 are collectively referred to as a silicon-on-insulator (SOI) structure.

The one or more transmitters and/or receivers 100TR are ICs configured to, respectively, generate one or more transmission signals at one or more signal terminals (not shown in FIG. 1) based on received data, and/or generate data from one or more transmission signals received at the same or an additional one or more signal terminals. In some embodiments, die D1 includes one or more additional ICs, e.g., logic, processing, memory ICs or the like, and the one or more transmitters and/or receivers 100TR are configured to receive and/or generate some or all of the data from/to the additional ICs.

In various embodiments, the one or more transmitters and/or receivers 100TR are configured to generate and/or receive the one or more transmission signals at a single signal terminal corresponding to a signal path, at a pair of signal terminals corresponding to differential signal paths, or two or more signal terminals corresponding to one or more signal paths and a ground path.

The one or more transmission signals have a corresponding equal number of one or more frequencies or a lesser number of one or more frequencies. As a given frequency of the one or more frequencies increases, a corresponding bandwidth increases, thereby increasing an amount of data that can be communicated over a given time period.

In some embodiments, the one or more transmitters and/or receivers 100TR are configured to generate and/or receive the one or more transmission signals having one or more frequencies corresponding to a radio frequency (RF) ranging from 30 kilohertz (kHz) to 300 gigahertz (GHz), e.g., an RF band.

In some embodiments, the one or more transmitters and/or receivers 100TR are configured to generate and/or receive the one or more transmission signals having one or more frequencies in a D-band ranging from 130 GHz to 174.8 GHz and corresponding to wavelengths ranging from 1.7 millimeters (mm) to 2.3 mm. In some embodiments, the one or more transmitters and/or receivers 100TR are configured to generate and/or receive one or more transmission signals having a frequency equal to 140 GHz.

In some embodiments, the one or more transmitters and/or receivers 100TR are configured to generate and/or receive the one or more transmission signals using frequency-division multiplexing (FDM) techniques and/or time-division multiplexing (TDM) techniques such as a time-division duplexing (TDD) technique as further discussed below with respect to FIG. 3.

The one or more transmitters and/or receivers 100TR, and in some embodiments additional ICs, include terminals (not shown) coupled to some or all of TSVs V1 and are thereby configured to, in operation, receive at least one power supply voltage, a reference voltage, e.g., ground, and one or more control, data, or other signals through TSVs V1, and perform the corresponding signal transmitting and/or receiving operations in response thereto.

Two or more circuit elements are considered to be coupled based on one or more direct electrical connections and/or one or more indirect electrical connections that include one or more switches or logic devices, e.g., an inverter or logic gate, between the two or more circuit elements. In some embodiments, electrical or signal communications between the two or more coupled circuit elements are capable of being modified, e.g., inverted or made conditional, by the one or more switches or logic devices.

In some embodiments in which IC package 100 includes PCB P1, some or all of TSVs V1 are bonded and electrically connected to PCB pads on PCB P1 through corresponding solder balls, and the one or more transmitters and/or receivers 100TR are thereby configured to, in operation, receive the at least one power supply voltage, reference voltage, and one or more control, data, or other signals through PCB P1.

Some or call of TSVs V1, and in some embodiments PCB P1, are thereby configured to distribute the at least one power supply voltage, reference voltage, and one or more control, data, or other signals to the one or more transmitters and/or receivers 100TR.

The one or more pads PD are positioned on a surface S3 of die D1 and electrically connected to corresponding signal terminal(s) of the one or more transmitters and/or receivers 100TR. The one or more pads PD and corresponding electrical connections include one or more conductive materials, e.g., one or more metals such as copper and/or aluminum.

The corresponding electrical connections include one or more metal interconnect layers between the one or more transmitters and/or receivers 100TR and the one or more pads PD. In some embodiments, the corresponding electrical connections include a redistribution layer (RDL) in addition to the metal interconnect layers.

Surface S3 and the one or more pads PD correspond to a topmost metal layer of the metal interconnect layers of die D1, and in some embodiments the RDL. In some embodiments, surface S3 is referred to as a first or front side of die D1 and surface S1 is referred to as a second or back side of die D1.

Passivation layer PS includes one or more insulating materials, e.g., SiO₂, un-doped silicate glass (USG), silicon nitride, and/or silicon oxynitride, is positioned on surface S3, and includes one or more openings corresponding to the one or more pads PD.

Antenna layers ANL are positioned on passivation layer PS and the one or more pads PD and include insulation layers INS1-IN3 and post-passivation interconnect (PPI) layers PPI1 and PPI2. Each of insulation layers INS1-IN3 includes one or more layers of insulating materials, e.g., polyimide, epoxy resin, acrylic resin, phenol resin, benzocyclobutene (BCB), polybenzoxazole (PBO), another suitable polymer-based dielectric material, SiO₂, silicon nitride, and/or silicon oxynitride. Each of PPI layers PPI1 and PPI2 includes one or more conductive materials, e.g., one or more metals such as copper and/or aluminum.

In the embodiment depicted in FIG. 1, insulation layers INS1-IN3 include PBO and are referred to as insulation layers PBO1-PBO3, and PPI layers PPI1 and PPI2 include copper and are referred to as PPI layers Cu-PPI 1 and Cu-PPI 2. Other combinations of materials are within the scope of the present disclosure.

Insulation layer INS1 overlies, e.g., is positioned on and directly contacts, passivation layer PS and the one or more pads PD and includes one or more openings aligned with the one or more pads PD in the Z direction.

PPI layer PPI1 includes one or more portions that overlie insulation layer INS1 and one or more portions PM1 that extend into the one or more openings in insulation layer INS1 aligned with the one or more pads PD. The one or more portions PM1 are electrically connected to, e.g., directly contact, the corresponding one or more pads PD.

Insulation layer INS2 overlies insulation layer INS1 and PPI layer PPI1, is adjacent to the one or more portions of PPI layer PPI1 that overlie insulation layer INS1, and includes one or more openings aligned in the Z direction with the one or more portions of PPI layer PPI1 that overlie insulation layer INS1.

PPI layer PPI2 includes one or more portions that overlie insulation layer INS2 and one or more portions PM2 that extend into the one or more openings in insulation layer INS2 corresponding to the one or more portions of PPI layer PPI1 that overlie insulation layer INS1. The one or more portions PM2 are electrically connected to, e.g., directly contact, the corresponding one or more portions of PPI layer PPI1.

Insulation layer INS3 overlies insulation layer INS2 and PPI layer PPI2, is adjacent to the one or more portions of PPI layer PPI2 that overlie insulation layer INS2, and includes one or more openings INS30 aligned in the Z direction with the one or more portions of PPI layer PPI2 that overlie insulation layer INS2.

At least one of the one or more portions of PPI layer PPI2 that overlie insulation layer INS2 includes one or more antenna structures AS, and at least one of the one or more openings INS30 is aligned with the corresponding at least one antenna structure AS, as further discussed below with respect to FIGS. 2A-2C. In some embodiments, at least one of the one or more portions of PPI layer PPI that overlie passivation layer PS includes one or more regions corresponding to a ground plane aligned in the Z direction with at least one of the one or more antenna structures AS.

In various embodiments, one or more of PPI layer PPI1, PPI layer PPI2, or insulation layers INS1-INS3 is, or collectively are, referred to as an antenna.

The arrangement of PPI layers PPI1 and PPI2 depicted in the cross-sectional view of FIG. 1 is a non-limiting example provided for the purpose of illustration. PPI layers PPI1 and PPI2 having arrangements other than that depicted in FIG. 1, e.g., including portions extending in the Y direction, are within the scope of the present disclosure.

A given instance of pad PD electrically connected to a signal terminal of a corresponding instance of transmitter and/or receiver 100TR is thereby also electrically connected to the overlying portion PM1 and corresponding one or more portions of PPI layer PPI1 that overlie insulation layer INS1. In various embodiments, a given overlying portion PM1 is electrically connected to a single portion of PPI layer PPI1 overlying insulation layer INS1 or electrically connected to multiple portions of PPI layer PPI1 overlying insulation layer INS1.

A given instance of a portion of PPI layer PPI1 overlying insulation layer INS1 is thereby also electrically connected to the overlying portion PM2 and corresponding one or more portions of PPI layer PPI2 that overlie insulation layer INS2. In various embodiments, a given overlying portion PM2 is electrically connected to a single portion of PPI layer PPI2 overlying insulation layer INS2 or electrically connected to multiple portions of PPI layer PPI2 overlying insulation layer INS2.

At least one signal terminal of a given instance of transmitter and/or receiver 100TR is thereby electrically connected to at least one antenna structure AS through the corresponding overlying portion PM1 and at least one portion of PPI layer PPI1 overlying insulation layer INS1 and the corresponding overlying portion(s) PM2 and portion(s) of PPI layer PPI2 overlying insulation layer INS2 and electrically connected to the underlying at least one portion of PPI layer PPI1.

In some embodiments, e.g., those in which a single signal terminal is electrically connected to a single antenna structure AS, some or all of a given portion PM1 and corresponding portion of PPI layer PPI1 overlying insulation layer INS1 is referred to as a conductive path.

In some embodiments, e.g., those in which multiple signal terminals are electrically connected to multiple antenna structures AS, PPI layer PPI1 is referred to as a network or an antenna network, and some or all of a given portion PM1 and one or more corresponding portions of PPI layer PPI1 overlying insulation layer INS1 is referred to as a conductive path, a network path, or an antenna network path.

In some embodiments, multiple signal terminals are electrically connected to two or more antenna structures AS configured as an antenna array, e.g., as discussed below with respect to FIG. 2C. In various embodiments, a given signal terminal is electrically connected to a single antenna structure AS of the array or to multiple antenna structures AS of the array, e.g., some or all of a row or column of the array.

In some embodiments, multiple transmitters and/or receivers of the one or more transmitters and/or receivers 100TR are configured to, in operation, perform a beamforming operation on the transmitted signal or direction-based operation on the received signal using the antenna array, as further discussed below with respect to FIG. 2C.

In a beamforming operation, the multiple transmitters generate multiple transmission signals having a same frequency and phase shifts corresponding to rows or columns of the array whereby multiple transmission signals are combined to form a wavefront having an angle relative to the X-Y plane (the X and Y directions corresponding to FIG. 1) based on the frequency, phase shifts, and spacing of the rows or columns.

In a direction-based operation, the received signal has phase shifts based on the row or column spacing, signal frequency, and angle relative to the X-Y plane. In various embodiments, the direction-based operation includes targeting or detecting the angle relative to the X-Y plane.

IC package 100 is thereby configured to include die D1 including the one or more transmitters and/or receivers 100TR, a pad PD electrically connected to the corresponding signal terminal, and passivation layer PS, PPI layer PPI1 including a conduction path electrically connected to pad PD, PPI layer PPI2 including an antenna structure AS electrically connected to the conduction path, and substrate SUB opposite passivation layer PS and including TSVs V1 electrically coupled to the one or more transmitters and/or receivers 100TR. IC package 100 thereby includes the one or more transmitters and/or receivers 100TR configured to transmit and/or receive signals through an antenna or antenna array on a front side of the die while being powered and controlled from a back side of the die through TSVs V1.

Operations of the one or more transmitters and/or receivers 100TR are thereby capable of being performed using IC package 100 having a lower cost and smaller form factor than in other approaches, e.g., those in which antenna, power, and control connections are on a same side of a die, those in which a transmitter/receiver and antenna are integrated in a single die, and/or those including a flip-chip or waveguide antenna.

FIGS. 2A-2C are plan views of antenna structures 200A-200C, in accordance with some embodiments. Each of antenna structures 200A-200C is a non-limiting example of an antenna structure usable as one or more instances of antenna structure AS discussed above with respect to FIG. 1.

Each of FIGS. 2A-2C depicts the X and Y directions and the corresponding one of antenna structures 200A-200C including one or more instances of PPI layer PPI2 including antenna structure AS, insulation layer INS3, and opening INS30 aligned with a corresponding antenna structure AS in the Z direction, each discussed above with respect to FIG. 1.

As depicted in FIG. 2A, antenna structure 200A corresponds to a patch antenna having a rectangular shape corresponding to a single portion of PPI layer PPI2 aligned with a single opening INS30. In some embodiments, the portion of PPI layer PPI2 aligned with opening INS30 has a shape other than a rectangle, e.g., a circle, triangle, or other polygon.

In some embodiments, antenna structure 200A corresponds to a patch antenna including more than one portion (not shown) of PPI layer PPI2 aligned with corresponding openings INS30. In some embodiments, antenna structure 200A includes a portion of PPI layer PPI1 configured as a ground plane (not shown) aligned with one or more portions of PPI layer PPI2 and corresponding opening(s) INS30.

In some embodiments, a total length in the X and/or Y direction of the one or more portions of PPI layer PPI2 corresponds to one half a wavelength of a transmission signal of the one or more transmitters and/or receivers 100TR discussed above with respect to FIG. 1, e.g., a total length ranging from 0.85 mm to 1.15 mm corresponding to the D-band frequency range.

As depicted in FIG. 2B, antenna structure 200B corresponds to a dipole antenna having two elongated segments aligned in the X direction corresponding to portions of PPI layer PPI2 aligned with a rectangular opening INS30. In some embodiments, the portions of PPI layer PPI2 aligned with opening INS30 correspond to separate signal paths of a differential signal. In some embodiments, the portions of PPI layer PPI2 aligned with opening INS30 include segments aligned in the Y direction and/or include more than two aligned segments, e.g., four segments.

In some embodiments, a total length of the dipole segments corresponds to one half a wavelength of a transmission signal of the one or more transmitters and/or receivers 100TR discussed above with respect to FIG. 1, e.g., a total length ranging from 0.85 mm to 1.15 mm corresponding to the D-band frequency range.

As depicted in FIG. 2C, antenna structure 200C corresponds to an antenna array including rows and columns of portions of PPI layer PPI2 and aligned openings INS30 configured as tiles, e.g., square or rectangular segments. In various embodiments, a given signal path corresponds to a single tile, some or all of a row of tiles, or some or all of a column of tiles.

In the embodiment depicted in FIG. 2C, antenna structure 200C includes totals of four rows and four columns. In various embodiments, antenna structure 200C includes totals of fewer or greater than four rows and/or fewer or greater than four columns, e.g., two rows and two columns, four rows and eight columns, eight rows and eight columns, or sixteen rows and sixteen columns.

As numbers of rows and/or columns increase, antenna area requirements increase and beam-forming and direction-based operations are improved with respect to transmission signals transmitted from or received by antenna 200C.

In the embodiment depicted in FIG. 2C, antenna structure 200C has a phased-array architecture including the columns spaced according to a pitch D. In some embodiments, antenna structure 200C has a phased-array architecture including the rows spaced according to pitch D.

In some embodiments, pitch D corresponds to one half a wavelength of a transmission signal of the one or more transmitters and/or receivers 100TR discussed above with respect to FIG. 1, e.g., a pitch ranging from 0.85 mm to 1.15 mm corresponding to the D-band frequency range.

By the configurations discussed above, IC package 100 including one of antenna structures 200A-200C as one or more instances of antenna structure AS is capable of realizing the benefits discussed above with respect to IC package 100.

FIG. 3 is a schematic diagram of transceiver circuit 300, in accordance with some embodiments. Transceiver circuit 300 is usable as some or all of the one or more transmitters and/or receivers 100TR discussed above with respect to FIG. 1.

Transceiver circuit 300 is a CMOS circuit including a total number N of transceivers 300-1-300-N. Each transceiver 300-1-300-N includes a transmitter Tx, a receiver Rx, and a switch SW coupled between each of transmitter Tx and receiver Rx and a corresponding signal terminal T1-TN.

In the embodiment depicted in FIG. 3, each of transmitter Tx, receiver Rx, switch SW, and corresponding signal terminal T1-TN corresponds to a single signal path. In some embodiments, each of transmitter Tx, receiver Rx, switch SW, and corresponding signal terminal T1-TN corresponds to more than one single signal path, e.g., a pair of signal paths corresponding to differential signals or including a ground reference.

Transmitter Tx includes an input terminal (not labeled) coupled to an amplifier, e.g., a power amplifier, configured to, in operation, output a transmission signal to switch SW based on a data signal received at the input terminal.

Receiver Rx includes an output terminal (not labeled) coupled to an amplifier, e.g., a low-noise amplifier, configured to, in operation, output a data signal at the output signal based on a transmission signal received from switch SW.

Switch SW includes one or more switching devices, e.g., transistors and/or transmission gates, configured to, in operation, couple one of transmitter Tx or receiver Rx to the corresponding signal terminal T1-TN responsive to one or more control signals.

In some embodiments, one or more of transceivers 300-1-300-N is thereby configured to perform a TDM operation, e.g., a TDD operation, based on switch SW alternating between coupling either transmitter Tx or receiver Rx to the corresponding signal terminal T1-TN.

In some embodiments, as discussed above with respect to FIG. 1, transceivers 300-1-300-N are configured to perform a beamforming operation using transmitters Tx and/or perform a direction-based operation using receivers Rx. In some embodiments, one or more of transceivers 300-1-300-N includes or is coupled to one or more phase-shifting, e.g., delay, elements (not shown).

In some embodiments, total number N is equal to one and transceiver circuit 300 corresponds to a single transceiver. In some embodiments, transceiver circuit 300 includes total number N equal to a number of rows or columns of an antenna array, e.g., antenna structure 200C discussed above with respect to FIG. 2C.

In some embodiments, transceiver circuit 300 includes total number N ranging from two to 32. In some embodiments, transceiver circuit 300 includes total number N ranging from four to eight. As total number N increases, circuit area requirements increase and beam-forming and direction-based operations are improved with respect to transmission signals transmitted from or received by transceiver circuit 300.

In some embodiments, transceiver circuit 300 is configured to operate at an RF frequency as discussed above with respect to FIG. 1. In some embodiments, transceiver circuit 300 is configured to operate at a frequency ranging from 130 GHz to 174.8 GHz. In some embodiments, transceiver circuit 300 is configured to operate at a frequency equal to 140 GHz.

By the configurations discussed above, IC package 100 including transceiver circuit 300 as some or all of the one or more transmitters and/or receivers 100TR is capable of realizing the benefits discussed above with respect to IC package 100.

FIG. 4 is a flowchart of method 400 of manufacturing an IC package, in accordance with some embodiments. Method 400 is operable, e.g., in accordance with the manufacturing flow discussed below with respect to FIG. 7, to form IC package 100 discussed above with respect to FIGS. 1-3.

FIGS. 5A-5P are cross-sectional views of IC package 100 at various manufacturing stages corresponding to method 400, in accordance with some embodiments. Each of FIGS. 5A-5P corresponds to a subset of the features depicted in FIG. 1 wherein the X and Y directions and some of the reference designators are not included for the purpose of clarity.

In some embodiments, the operations of method 400 are performed in the order depicted in FIG. 4. In some embodiments, the operations of method 400 are performed in an order other than the order of FIG. 4. In some embodiments, one or more additional operations are performed before, during, between, and/or after the operations of method 400.

In some embodiments, one or more of the operations of method 400 are a subset of operations of a method of forming a WLCSP.

At operation 410, in some embodiments, a plurality of TSVs is formed in a substrate. Forming the plurality of TSVs includes forming the plurality of TSVs extending through the substrate. In some embodiments, forming the plurality of TSVs in the substrate includes forming TSVs V1 in substrate SUB discussed above with respect to FIG. 1.

In some embodiments, forming the plurality of TSVs in the substrate includes forming the plurality of TSVs as part of an SOI process.

FIG. 5A depicts IC package 100 including substrate SUB prior to the formation of the plurality of TSVs, and FIG. 5B depicts IC package 100 including substrate SUB after the formation of the plurality of TSVs (V1).

Each of FIGS. 5C-5L depicts substrate SUB including the plurality of TSVs in accordance with embodiments in which operation 410 is performed. In embodiments in which operation 470, discussed below, is performed instead of operation 410, substrate SUB does not include the plurality of TSVs as depicted in FIGS. 5C-5L.

Forming the plurality of TSVs includes performing multiple manufacturing operations, e.g., one or more of a lithography, etching, deposition, or other operation suitable for performing a suitable patterning method corresponding to the plurality of TSVs.

At operation 420, a CMOS layer including one or more transmitters and/or receivers is constructed on the substrate, the one or more transmitters and/or receivers including corresponding one or more signal terminals. In some embodiments, constructing the CMOS layer includes constructing the CMOS layer in die D1 including substrate SUB and the one or more transmitters and/or receivers 100TR discussed above with respect to FIG. 1.

In some embodiments, constructing the CMOS layer including the one or more transmitters and/or receivers including corresponding one or more signal terminals includes constructing transceiver circuit 300 including one or more signal terminals T1-TN discussed above with respect to FIG. 3.

In some embodiments, constructing the CMOS layer includes constructing the CMOS layer including one or more circuits in addition to the one or more transmitters and/or receivers, e.g., one or more logic, processing, memory ICs, or the like.

Constructing the CMOS layer includes constructing a metal interconnect structure including one or more electrical connections from each of the one or more signal terminals to a top metal layer of the metal interconnect structure.

In some embodiments, constructing the CMOS layer on the substrate includes forming an insulation layer and constructing the CMOS layer on the insulation layer as part of an SOI process, e.g., including depositing an epitaxial layer of silicon on the insulation layer. In some embodiments, constructing the CMOS layer on the substrate includes constructing the CMOS layer continuous with the substrate.

In embodiments in which operation 410 is performed, constructing the CMOS layer also includes constructing electrical connections from the one or more transmitters and/or receivers to the plurality of TSVs. In embodiments in which operation 470 is performed instead of operation 410, constructing the CMOS layer includes constructing the one or more transmitters and/or receivers configured to be electrically connected to a plurality of TSVs subsequent to the formation of the CMOS layer.

FIG. 5C depicts IC package 100 including the CMOS layer constructed on substrate SUB in die D1.

Constructing the CMOS layer including the one or more transmitters and/or receivers includes forming one or more structures and/or devices, e.g., transistor features including S/D structures in active areas of the semiconductor die, gate structures on and/or in the active areas, and electrical connections between the devices in accordance with an IC design.

Constructing the CMOS layer including the one or more transmitters and/or receivers thereby includes performing multiple manufacturing operations, e.g., one or more of a lithography, diffusion, deposition, etching, planarizing, or other operation suitable for building the CMOS transistor features.

In some embodiments, constructing the MOS layer including the one or more transmitters and/or receivers includes performing one or more front end of line (FEOL) and/or back end of line (BEOL) operations.

At operation 430, at least one pad and a passivation layer are formed on the CMOS layer. Forming the at least one pad includes forming at least one electrical connection to the top metal layer of the metal interconnect structure, thereby electrically connecting each pad of the at least one pad to a corresponding signal terminal of the one or more transmitters and/or receivers.

Forming the passivation layer includes forming one or more portions of the passivation layer overlying the at least one pad and including one or more openings aligned with each pad of the at least one pad in the Z direction.

In some embodiments, forming the at least one pad and the passivation layer includes forming at least one instance of pad PD and passivation layer PS on the CMOS layer as discussed above with respect to FIG. 1.

FIG. 5D depicts IC package 100 including the at least one pad on the CMOS layer, and FIG. 5E depicts IC package 100 including the passivation layer on the CMOS layer and overlying the at least one pad.

Forming the at least one pad and the passivation layer on the CMOS layer includes performing multiple manufacturing operations, e.g., one or more of a lithography, etching, deposition, spin-on coating, or other operation suitable for performing a suitable patterning and formation method corresponding to the at least one pad and the passivation layer including one or more openings aligned with each pad of the at least one pad.

At operation 440, a first insulation layer and a first metal layer are formed on the passivation layer, the first metal layer including at least one conductive path electrically connected to the at least one pad.

Forming the first insulation layer includes forming one or more portions of the first insulation layer overlying the at least one pad and including one or more openings aligned with each pad of the at least one pad in the Z direction.

In some embodiments, forming the first insulation layer and first metal layer includes forming PPI layer PPI1 and insulation layer INS1, PPI layer PPI1 including each conductive path of the at least one conductive path electrically connected to a corresponding pad PD of the at least one pad PD on the CMOS layer as discussed above with respect to FIG. 1.

FIG. 5F depicts IC package 100 including first insulation layer INS1 on an instance of PAD and the passivation layer, FIG. 5G depicts IC package 100 including an opening in insulation layer INS1 aligned with the instance of PAD in the Z direction, and FIG. 5H depicts IC package 100 including PPI layer PPI1 electrically connected to the instance of PAD.

Forming the first insulation layer and first metal layer includes performing multiple manufacturing operations, e.g., one or more of a lithography, etching, deposition, spin-on coating, or other operation suitable for performing a suitable patterning and formation method corresponding to the first metal layer and the first insulation layer including one or more openings aligned with each pad of the at least one pad.

At operation 450, a second insulation layer and a second metal layer are formed on the first metal layer, the second metal layer including at least one antenna structure electrically connected to the at least one conductive path.

Forming the second insulation layer includes forming one or more portions of the second insulation layer overlying the at least one conductive path and including one or more openings aligned with each conductive path of the at least one conductive path in the Z direction.

In some embodiments, forming the second insulation layer and second metal layer includes forming PPI layer PPI2 and insulation layer INS2, PPI layer PPI2 including each antenna structure AS of the at least one antenna structure AS electrically connected to a corresponding conductive path of the at least one conductive path in PPI layer PPI1 as discussed above with respect to FIG. 1.

In some embodiments, forming the second metal layer including at least one antenna structure electrically connected to the at least one conductive path includes forming one or more of antenna structures 200A-220C discussed above with respect to FIGS. 2A-2C.

FIG. 5I depicts IC package 100 including second insulation layer INS2 on PPI layer PPI1 and first insulation layer INS1, FIG. 5J depicts IC package 100 including an opening in insulation layer INS2 aligned with a conductive path of PPI layer PPI1 in the Z direction, and FIG. 5K depicts IC package 100 including PPI layer PPI2 electrically connected to the conductive path of PPI layer PPI1.

Forming the second insulation layer and second metal layer includes performing multiple manufacturing operations, e.g., one or more of a lithography, etching, deposition, spin-on coating, or other operation suitable for performing a suitable patterning and formation method corresponding to the second metal layer including one or more antenna structures and the second insulation layer including one or more openings aligned with each conductive path of the at least one conductive path.

At operation 460, a third insulation layer is formed on the second metal layer, the third insulation layer including one or more openings aligned with the at least one antenna structure in the Z direction.

In some embodiments, forming the third insulation layer includes forming insulation layer INS3 including one or more openings aligned with each antenna structure AS of the at least one antenna structure AS in PPI layer PPI2 as discussed above with respect to FIG. 1.

In some embodiments, forming the one or more openings in the third insulation layer includes forming the one or more openings aligned with one or more of antenna structures 200A-220C discussed above with respect to FIGS. 2A-2C.

FIG. 5L depicts IC package 100 including third insulation layer INS3 on PPI layer PPI2 and second insulation layer INS2, and FIG. 5M depicts IC package 100 including opening INS30 in insulation layer INS3 aligned with an antenna structure AS of PPI layer PPI2 in the Z direction.

Forming the third insulation layer includes performing multiple manufacturing operations, e.g., one or more of a lithography, etching, deposition, spin-on coating, or other operation suitable for performing a suitable patterning and formation method corresponding to the third insulation layer including one or more openings aligned with each antenna structure of the at least one antenna structure.

At operation 470, in some embodiments, a plurality of TSVs is formed in the substrate. Forming the plurality of TSVs includes forming the plurality of TSVs extending through the substrate. In some embodiments, forming the plurality of TSVs in the substrate includes forming TSVs V1 in substrate SUB discussed above with respect to FIG. 1.

In various embodiments, forming the plurality of TSVs in the substrate includes forming one or more TSVs instead of or in addition to forming one or more TSVs as part of performing operation 410 discussed above.

In some embodiments, forming the plurality of TSVs in the substrate includes forming the plurality of TSVs in a back side of a semiconductor die, e.g., die D1.

FIG. 5O depicts IC package 100 including substrate SUB prior to the formation of the plurality of TSVs, and FIG. 5P depicts IC package 100 including substrate SUB after the formation of the plurality of TSVs (V1).

Forming the plurality of TSVs includes performing multiple manufacturing operations, e.g., one or more of a lithography, etching, deposition, or other operation suitable for performing a suitable patterning method corresponding to the plurality of TSVs.

At operation 480, the substrate is bonded to a PCB. Bonding the substrate to the PCB includes forming mechanical and electrical attachments between the substrate and the PCB. In some embodiments, bonding the substrate to the PCB includes bonding substrate SUB to PCB P1 at surface S1 discussed above with respect to FIG. 1.

In some embodiments, bonding the substrate to the PCB includes electrically connecting the plurality of TSVs of the substrate to a plurality of traces, e.g., including solder or other bonding pads, on a surface of the PCB.

In some embodiments, bonding the substrate to the PCB includes attaching solder balls to the plurality of TSVs and/or the PCB.

In some embodiments, bonding the substrate to the PCB includes performing one or more die separation, e.g., slicing, operations prior to or after attaching solder balls to the TSVs, e.g., as part of a WLCSP process.

In some embodiments, bonding the substrate to the PCB includes performing one or more soldering operations, e.g., a reflow operation.

FIG. 5N depicts IC package 100 including substrate SUB attached to the PCB, e.g., as some or all of a WLCSP.

By performing some or all of the operations of method 400, an IC package is manufactured including one or more transmitters and/or receivers configured to transmit and/or receive signals through an antenna or antenna array on a front side of a die while being powered and controlled from a back side of the die through a plurality of TSVs, thereby enabling the benefits discussed above with respect to IC package 100.

FIG. 6 is a flowchart of a method 600 of operating an IC package, in accordance with some embodiments. Method 600 is usable with an IC package, e.g., IC package 100 discussed above with respect to FIGS. 1-5P.

The sequence in which the operations of method 600 are depicted in FIG. 6 is for illustration only; the operations of method 600 are capable of being executed in sequences that differ from that depicted in FIG. 6. In some embodiments, operations in addition to those depicted in FIG. 6 are performed before, between, during, and/or after the operations depicted in FIG. 6. In some embodiments, the operations of method 600 are a subset of a method of operating a telecommunication device, radar apparatus, or the like.

At operation 610, a power supply voltage, a reference voltage, and one or more control and/or data signals are received at a plurality of TSVs in a substrate positioned on a first side of a die.

Receiving the power supply voltage, reference voltage, and one or more control and/or data signals includes receiving the power supply voltage, reference voltage, and one or more control and/or data signals at surface S1 of substrate SUB positioned on the back side of die D1, discussed above with respect to FIGS. 1-5P.

At operation 620, in response to the power supply voltage, reference voltage, and one or more control and/or data signals, a transmitter and/or receiver on the die are used to output and/or receive a transmission signal at a signal terminal.

Using the transmitter and/or receiver to output and/or receive the transmission signal in response to the power supply voltage, reference voltage, and one or more control and/or data signals includes using the one or more transmitters and receivers 100TR discussed above with respect to FIGS. 1-3.

In some embodiments, using the transmitter and/or receiver to output and/or receive the transmission signal at the signal terminal in response to the power supply voltage, reference voltage, and one or more control and/or data signals includes using transceiver 300 discussed above with respect to FIG. 3.

In various embodiments, using the transmitter and/or receiver to output and/or receive the transmission signal at the signal terminal in response to the power supply voltage, reference voltage, and one or more control and/or data signals includes performing one or more of a FDM, TDM, TDD, beamforming, or direction-based operation.

At operation 630, the transmission signal is received and/or transmitted from/to the signal terminal at an antenna structure in a PPI layer positioned on a second side of the die opposite the first side of the die.

Receiving and/or transmitting the transmission signal at the antenna structure in the PPI layer positioned on the second side of the die opposite the first side of the die includes receiving and/or transmitting the transmission signal at antenna structure AS in PPI layer PPI2 positioned on the front side of die D1 discussed above with respect to FIGS. 1-3.

In some embodiments, receiving and/or transmitting the transmission signal at the antenna structure includes receiving and/or transmitting the transmission signal at one or more of antenna structures 200A-200C discussed above with respect to FIGS. 2A-2C.

In various embodiments, receiving and/or transmitting the transmission signal from/to the signal terminal at the antenna structure in the PPI layer positioned on the second side of the die opposite the first side of the die includes performing one or more of a FDM, TDM, TDD, beamforming, or direction-based operation.

By performing some or all of the operations of method 600, operations are performed using an IC package including one or more transmitters and/or receivers configured to transmit and/or receive signals through an antenna or antenna array on a front side of a die while being powered and controlled from a back side of the die through a plurality of TSVs, thereby enabling the benefits discussed above with respect to IC package 100.

FIG. 7 is a block diagram of IC manufacturing system 700, and an IC manufacturing flow associated therewith, in accordance with some embodiments. In some embodiments, based on an IC layout diagram, at least one of (A) one or more semiconductor masks or (B) at least one component in a layer of a semiconductor integrated circuit is fabricated using manufacturing system 700. Manufacturing system 700 and the associated manufacturing flow are usable to perform some or all of method 400 discussed above with respect to FIGS. 4-5P.

In FIG. 7, IC manufacturing system 700 includes entities, such as a design house 720, a mask house 730, and an IC manufacturer/fabricator (“fab”) 750, that interact with one another in the design, development, and manufacturing cycles and/or services related to manufacturing an IC device 760. The entities in system 700 are connected by a communications network. In some embodiments, the communications network is a single network. In some embodiments, the communications network is a variety of different networks, such as an intranet and the Internet. The communications network includes wired and/or wireless communication channels. Each entity interacts with one or more of the other entities and provides services to and/or receives services from one or more of the other entities. In some embodiments, two or more of design house 720, mask house 730, and IC fab 750 is owned by a single larger company. In some embodiments, two or more of design house 720, mask house 730, and IC fab 750 coexist in a common facility and use common resources.

Design house (or design team) 720 generates an IC design layout diagram 722. IC design layout diagram 722 includes various geometrical patterns. The geometrical patterns correspond to patterns of metal, oxide, or semiconductor layers that make up the various components of IC device 760 to be fabricated. The various layers combine to form various IC features. For example, a portion of IC design layout diagram 722 includes various IC features, such as an active region, gate electrode, source and drain, metal lines or vias of an interlayer interconnection, and openings for bonding pads, to be formed in a semiconductor substrate (such as a silicon wafer) and various material layers disposed on the semiconductor substrate. Design house 720 implements a proper design procedure to form IC design layout diagram 722. The design procedure includes one or more of logic design, physical design or place and route. IC design layout diagram 722 is presented in one or more data files having information of the geometrical patterns. For example, IC design layout diagram 722 can be expressed in a GDSII file format or DFII file format.

Mask house 730 includes data preparation 732 and mask fabrication 744. Mask house 730 uses IC design layout diagram 722 to manufacture one or more masks 745 to be used for fabricating the various layers of IC device 760 according to IC design layout diagram 722. Mask house 730 performs mask data preparation 732, where IC design layout diagram 722 is translated into a representative data file (RDF). Mask data preparation 732 provides the RDF to mask fabrication 744. Mask fabrication 744 includes a mask writer. A mask writer converts the RDF to an image on a substrate, such as a mask (reticle) 745 or a semiconductor wafer 753. The design layout diagram 722 is manipulated by mask data preparation 732 to comply with particular characteristics of the mask writer and/or requirements of IC fab 750. In FIG. 7, mask data preparation 732 and mask fabrication 744 are illustrated as separate elements. In some embodiments, mask data preparation 732 and mask fabrication 744 can be collectively referred to as mask data preparation.

In some embodiments, mask data preparation 732 includes optical proximity correction (OPC) which uses lithography enhancement techniques to compensate for image errors, such as those that can arise from diffraction, interference, other process effects and the like. OPC adjusts IC design layout diagram 722. In some embodiments, mask data preparation 732 includes further resolution enhancement techniques (RET), such as off-axis illumination, sub-resolution assist features, phase-shifting masks, other suitable techniques, and the like or combinations thereof. In some embodiments, inverse lithography technology (ILT) is also used, which treats OPC as an inverse imaging problem.

In some embodiments, mask data preparation 732 includes a mask rule checker (MRC) that checks the IC design layout diagram 722 that has undergone processes in OPC with a set of mask creation rules which contain certain geometric and/or connectivity restrictions to ensure sufficient margins, to account for variability in semiconductor manufacturing processes, and the like. In some embodiments, the MRC modifies the IC design layout diagram 722 to compensate for limitations during mask fabrication 744, which may undo part of the modifications performed by OPC in order to meet mask creation rules.

In some embodiments, mask data preparation 732 includes lithography process checking (LPC) that simulates processing that will be implemented by IC fab 750 to fabricate IC device 760. LPC simulates this processing based on IC design layout diagram 722 to create a simulated manufactured device, such as IC device 760. The processing parameters in LPC simulation can include parameters associated with various processes of the IC manufacturing cycle, parameters associated with tools used for manufacturing the IC, and/or other aspects of the manufacturing process. LPC takes into account various factors, such as aerial image contrast, depth of focus (“DOF”), mask error enhancement factor (“MEEF”), other suitable factors, and the like or combinations thereof. In some embodiments, after a simulated manufactured device has been created by LPC, if the simulated device is not close enough in shape to satisfy design rules, OPC and/or MRC are be repeated to further refine IC design layout diagram 722.

It should be understood that the above description of mask data preparation 732 has been simplified for the purposes of clarity. In some embodiments, data preparation 732 includes additional features such as a logic operation (LOP) to modify the IC design layout diagram 722 according to manufacturing rules. Additionally, the processes applied to IC design layout diagram 722 during data preparation 732 may be executed in a variety of different orders.

After mask data preparation 732 and during mask fabrication 744, a mask 745 or a group of masks 745 are fabricated based on the modified IC design layout diagram 722. In some embodiments, mask fabrication 744 includes performing one or more lithographic exposures based on IC design layout diagram 722. In some embodiments, an electron-beam (e-beam) or a mechanism of multiple e-beams is used to form a pattern on a mask (photomask or reticle) 745 based on the modified IC design layout diagram 722. Mask 745 can be formed in various technologies. In some embodiments, mask 745 is formed using binary technology. In some embodiments, a mask pattern includes opaque regions and transparent regions. A radiation beam, such as an ultraviolet (UV) or EUV beam, used to expose the image sensitive material layer (e.g., photoresist) which has been coated on a wafer, is blocked by the opaque region and transmits through the transparent regions. In one example, a binary mask version of mask 745 includes a transparent substrate (e.g., fused quartz) and an opaque material (e.g., chromium) coated in the opaque regions of the binary mask. In another example, mask 745 is formed using a phase shift technology. In a phase shift mask (PSM) version of mask 745, various features in the pattern formed on the phase shift mask are configured to have proper phase difference to enhance the resolution and imaging quality. In various examples, the phase shift mask can be attenuated PSM or alternating PSM. The mask(s) generated by mask fabrication 744 is used in a variety of processes. For example, such a mask(s) is used in an ion implantation process to form various doped regions in semiconductor wafer 753, in an etching process to form various etching regions in semiconductor wafer 753, and/or in other suitable processes.

IC fab 750 is an IC fabrication business that includes one or more manufacturing facilities for the fabrication of a variety of different IC products. In some embodiments, IC Fab 750 is a semiconductor foundry. For example, there may be a manufacturing facility for the front end fabrication of a plurality of IC products (front-end-of-line (FEOL) fabrication), while a second manufacturing facility may provide the back end fabrication for the interconnection and packaging of the IC products (back-end-of-line (BEOL) fabrication), and a third manufacturing facility may provide other services for the foundry business.

IC fab 750 includes wafer fabrication tools 752 configured to execute various manufacturing operations on semiconductor wafer 753 such that IC device 760 is fabricated in accordance with the mask(s), e.g., mask 745. In various embodiments, fabrication tools 752 include one or more of a wafer stepper, an ion implanter, a photoresist coater, a process chamber, e.g., a CVD chamber or LPCVD furnace, a CMP system, a plasma etch system, a wafer cleaning system, or other manufacturing equipment capable of performing one or more suitable manufacturing processes as discussed herein.

IC fab 750 uses mask(s) 745 fabricated by mask house 730 to fabricate IC device 760. Thus, IC fab 750 at least indirectly uses IC design layout diagram 722 to fabricate IC device 760. In some embodiments, semiconductor wafer 753 is fabricated by IC fab 750 using mask(s) 745 to form IC device 760. In some embodiments, the IC fabrication includes performing one or more lithographic exposures based at least indirectly on IC design layout diagram 722. Semiconductor wafer 753 includes a silicon substrate or other proper substrate having material layers formed thereon. Semiconductor wafer 753 further includes one or more of various doped regions, dielectric features, multilevel interconnects, and the like (formed at subsequent manufacturing steps).

In some embodiments, an IC package includes a transmitter and/or receiver positioned in a semiconductor die and including a signal terminal, a pad positioned on a first surface of the semiconductor die, wherein the pad is electrically connected to the signal terminal, a passivation layer positioned on the first surface and including a first opening aligned with the pad, a first PPI layer including a conductive path electrically connected to the pad, a second PPI layer including an antenna structure electrically connected to the conductive path, and a substrate positioned on a second surface of the semiconductor die opposite the passivation layer, the substrate including a plurality of TSVs electrically coupled to the transmitter and/or receiver. In some embodiments, the antenna structure includes a patch antenna or a dipole antenna. In some embodiments, the IC package includes a first insulation layer positioned on the passivation layer, wherein the conductive path is positioned on the first insulation layer, a second insulation layer positioned on the first insulation layer, wherein the antenna structure is positioned on the second insulation layer, and a third insulation layer positioned on the second insulation layer and including a second opening aligned with the antenna structure. In some embodiments, the IC package includes a PCB bonded to the substrate and including a plurality of traces electrically connected to the plurality of TSVs. In some embodiments, the transmitter and/or receiver is configured to receive a power supply voltage and one or more control signals through the plurality of TSVs. In some embodiments, the transmitter and/or receiver includes each of a transmitter and a receiver and a switching device coupled between the signal terminal and each of the transmitter and the receiver, and the transceiver is configured to perform a time division duplexing operation. In some embodiments, the transmitter and/or receiver is configured to operate at a frequency ranging from 130 GHz to 174.8 GHz. In some embodiments, the semiconductor die, the first and second PPI layers, and the substrate are configured as a WLCSP.

In some embodiments, an IC package includes a plurality of transceivers positioned in a semiconductor die, a plurality of pads positioned on a first surface of the semiconductor die, wherein each pad of the plurality of pads is electrically connected to a signal terminal of a corresponding transceiver of the plurality of transceivers, a passivation layer positioned on the first surface and including a plurality of first openings aligned with corresponding pads of the plurality of pads, a first PPI layer including a plurality of network paths electrically connected to corresponding pads of the plurality of pads, a second PPI layer including an antenna array including a plurality of tiles electrically connected to corresponding paths of the plurality of network paths, and a substrate positioned on a second surface of the semiconductor die opposite the passivation layer, the substrate including a plurality of TSVs electrically coupled to the plurality of transceivers. In some embodiments, the IC package includes a first insulation layer positioned on the passivation layer, wherein the plurality of network paths is positioned on the first insulation layer, a second insulation layer positioned on the first insulation layer, wherein the plurality of tiles of the antenna array is positioned on the second insulation layer, and a third insulation layer positioned on the second insulation layer and including a plurality of second openings aligned with corresponding tiles of the plurality of tiles. In some embodiments, the plurality of tiles has a phased-array architecture including columns of tiles spaced according to a pitch of half a wavelength of a transmission signal, and the plurality of transceivers is configured to perform a beamforming operation on the transmission signal using the antenna array. In some embodiments, the plurality of transceivers is configured to output the transmission signal having a frequency of 140 GHz. In some embodiments, the IC package includes a PCB bonded to the substrate and including a plurality of traces electrically connected to the plurality of TSVs, wherein the plurality of TSVs is configured to distribute a power supply voltage and one or more control signals to the plurality of transceivers. In some embodiments, each transceiver of the plurality of transceivers includes a switching device coupled between the corresponding signal terminal and each of a transmitter and a receiver, and the plurality of transceivers is configured to perform a time division duplexing operation. In some embodiments, the semiconductor die, the first and second PPI layers, and the substrate are configured as a WLCSP.

In some embodiments, a method of manufacturing an IC package includes constructing a CMOS layer including a transmitter and/or receiver on a substrate, wherein the transmitter and/or receiver includes a signal terminal, forming a pad and a passivation layer on the CMOS layer, wherein the forming the pad includes forming an electrical connection between the signal terminal and the pad, forming a first insulation layer and a first metal layer on the passivation layer, wherein the first metal layer includes a conductive path electrically connected to the pad, forming a second insulation layer and a second metal layer on the first metal layer, wherein the second metal layer includes an antenna structure electrically connected to the conductive path, forming a third insulation layer on the second metal layer, wherein the third insulation layer includes an opening aligned with the antenna structure, and forming a TSV in the substrate, wherein the TSV is electrically coupled to the transmitter and/or receiver. In some embodiments, constructing the CMOS layer including the transmitter and/or receiver on the substrate includes constructing a plurality of transmitters including the transmitter, the plurality of transmitters includes a plurality of signal terminals including the signal terminal, forming the second metal layer includes forming a plurality of antenna structures including the antenna structure, and each antenna structure of the plurality of antenna structures is electrically connected to a signal terminal of the plurality of signal terminals. In some embodiments, the method includes bonding the substrate to a PCB. In some embodiments, forming the TSV is performed prior to constructing the PMOS layer. In some embodiments, forming the third insulation layer is performed prior to forming the TSV.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

1. An integrated circuit (IC) package comprising:
a transmitter and/or receiver positioned in a semiconductor die and comprising a signal terminal;
a pad positioned on a first surface of the semiconductor die, wherein the pad is electrically connected to the signal terminal;
a passivation layer positioned on the first surface and comprising a first opening aligned with the pad;
a first post-passivation interconnect (PPI) layer comprising a conductive path electrically connected to the pad;
a second PPI layer comprising an antenna structure electrically connected to the conductive path; and
a substrate positioned on a second surface of the semiconductor die opposite the passivation layer, the substrate comprising a plurality of through-substrate vias (TSVs) electrically coupled to the transmitter and/or receiver.

2. The IC package of claim 1, wherein
the antenna structure comprises a patch antenna or a dipole antenna.

3. The IC package of claim 1, further comprising:
a first insulation layer positioned on the passivation layer, wherein the conductive path is positioned on the first insulation layer;
a second insulation layer positioned on the first insulation layer, wherein the antenna structure is positioned on the second insulation layer; and
a third insulation layer positioned on the second insulation layer and comprising a second opening aligned with the antenna structure.

4. The IC package of claim 1, further comprising:
a printed circuit board (PCB) bonded to the substrate and comprising a plurality of traces electrically connected to the plurality of TSVs.

5. The IC package of claim 1, wherein
the transmitter and/or receiver is configured to receive a power supply voltage and one or more control signals through the plurality of TSVs.

6. The IC package of claim 1, wherein
the transmitter and/or receiver comprises each of a transmitter and a receiver and a switching device coupled between the signal terminal and each of the transmitter and the receiver, and
the transmitter and/or receiver is configured to perform a time division duplexing operation.

7. The IC package of claim 1, wherein
the transmitter and/or receiver is configured to operate at a frequency ranging from 130 gigahertz (GHz) to 174.8 GHz.

8. The IC package of claim 1, wherein
the semiconductor die, the first and second PPI layers, and the substrate are configured as a wafer-level chip-scale package (WLCSP).

9. An integrated circuit (IC) package comprising:
a plurality of transceivers positioned in a semiconductor die;
a plurality of pads positioned on a first surface of the semiconductor die, wherein each pad of the plurality of pads is electrically connected to a signal terminal of a corresponding transceiver of the plurality of transceivers;
a passivation layer positioned on the first surface and comprising a plurality of first openings aligned with corresponding pads of the plurality of pads;
a first post-passivation interconnect (PPI) layer comprising a plurality of network paths electrically connected to corresponding pads of the plurality of pads;
a second PPI layer comprising an antenna array comprising a plurality of tiles electrically connected to corresponding paths of the plurality of network paths; and
a substrate positioned on a second surface of the semiconductor die opposite the passivation layer, the substrate comprising a plurality of through-substrate vias (TSVs) electrically coupled to the plurality of transceivers.

10. The IC package of claim 9, further comprising:
a first insulation layer positioned on the passivation layer, wherein the plurality of network paths is positioned on the first insulation layer;
a second insulation layer positioned on the first insulation layer, wherein the plurality of tiles of the antenna array is positioned on the second insulation layer; and
a third insulation layer positioned on the second insulation layer and comprising a plurality of second openings aligned with corresponding tiles of the plurality of tiles.

11. The IC package of claim 9, wherein
the plurality of tiles has a phased-array architecture comprising columns of tiles spaced according to a pitch of half a wavelength of a transmission signal, and
the plurality of transceivers is configured to perform a beamforming operation on the transmission signal using the antenna array.

12. The IC package of claim 11, wherein
the plurality of transceivers is configured to output the transmission signal having a frequency of 140 gigahertz (GHz).

13. The IC package of claim 9, further comprising:
a printed circuit board (PCB) bonded to the substrate and comprising a plurality of traces electrically connected to the plurality of TSVs,
wherein the plurality of TSVs is configured to distribute a power supply voltage and one or more control signals to the plurality of transceivers.

14. The IC package of claim 9, wherein
each transceiver of the plurality of transceivers comprises a switching device coupled between the corresponding signal terminal and each of a transmitter and a receiver, and
the plurality of transceivers is configured to perform a time division duplexing operation.

15. The IC package of claim 9, wherein
the semiconductor die, the first and second PPI layers, and the substrate are configured as a wafer-level chip-scale package (WLCSP).

16. A method of manufacturing an integrated circuit (IC) package, the method comprising:
constructing a complementary metal-oxide-semiconductor (CMOS) layer comprising a transmitter and/or receiver on a substrate, wherein the transmitter and/or receiver comprises a signal terminal;
forming a pad and a passivation layer on the CMOS layer, wherein the forming the pad comprises forming an electrical connection between the signal terminal and the pad;
forming a first insulation layer and a first metal layer on the passivation layer, wherein the first metal layer comprises a conductive path electrically connected to the pad;
forming a second insulation layer and a second metal layer on the first metal layer, wherein the second metal layer comprises an antenna structure electrically connected to the conductive path;
forming a third insulation layer on the second metal layer, wherein the third insulation layer comprises an opening aligned with the antenna structure; and
forming a through-substrate via (TSV) in the substrate, wherein the TSV is electrically coupled to the transmitter and/or receiver.

17. The method of claim 16, wherein
the constructing the CMOS layer comprising the transmitter and/or receiver on the substrate comprises constructing a plurality of transmitters comprising the transmitter,
the plurality of transmitters comprises a plurality of signal terminals comprising the signal terminal,
the forming the second metal layer comprises forming a plurality of antenna structures comprising the antenna structure, and
each antenna structure of the plurality of antenna structures is electrically connected to a signal terminal of the plurality of signal terminals.

18. The method of claim 16, further comprising:
bonding the substrate to a printed circuit board (PCB).

19. The method of claim 16, wherein
the forming the TSV is performed prior to the constructing the CMOS layer.

20. The method of claim 16, wherein
the forming the third insulation layer is performed prior to the forming the TSV.
